(19) United States
(12) Patent Application Publication
(10) Pub. No.: US 2025/0100872 A1
(43) Pub. Date: Mar. 27, 2025

(54) AIRFLOW SENSOR AND AIRFLOW SENSOR PACKAGING STRUCTURE

(71) Applicant: Memsensing Microsystems (Suzhou, China) Co., Ltd., Suzhou (CN)

(72) Inventor: Yanzi MENG, Suzhou (CN)

(73) Assignee: Memsensing Microsystems (Suzhou, China) Co., Ltd., Suzhou (CN)

(21) Appl. No.: 18/889,496

(22) Filed: Sep. 19, 2024

(30) Foreign Application Priority Data
Sep. 26, 2023 (CN) 202311252105.1

(51) Int. Cl. B81B 7/00; G01L 9/00; G01L 9/12

(52) U.S. Cl. CPC B81B 7/0061; G01L 9/0072; G01L 9/12; B81B 2201/0292; B81B 2203/0127; B81B 2203/0315; B81B 2203/0338; B81B 2203/0353; B81B 2203/04

(57) ABSTRACT

Disclosed an airflow sensor and an airflow sensor packaging structure. a substrate, a vibrating electrode, and a fixed electrode in a laminated arrangement, wherein the substrate has a back cavity passing through in its thickness direction. it is intended to provide at least one pressure equalizing structure on the airflow sensor, and the pressure equalizing structure physically isolating itself from the gap layer, so as to establish a continuous flow path in the space between the back cavity of the airflow sensor and the space outside the airflow sensor.

### CROSS-REFERENCE TO RELATED APPLICATIONS

This application claims the benefit of priority of China Patent application Ser. No. 20/231,1252105.1, filed with the China National Intellectual Property Administration on Sep. 26, 2023 and entitled “AIRFLOW SENSOR AND AIRFLOW SENSOR PACKAGING STRUCTURE”, the disclosures of which are incorporated by reference herein in their entirety.

### TECHNICAL FIELD

This present invention relates to an airflow sensor technical field, and more specifically to an airflow sensor and an airflow sensor packaging structure.

### BACKGROUND

Devices manufactured based on Micro-Electro-Mechanical System (MEMS) are called MEMS devices. The device of the MEMS capacitive pressure sensor comprises a diaphragm and a backplane, and there is a gap between the diaphragm and the backplane. Changes in air pressure will cause the diaphragm to deform, and the capacitor between the diaphragm and the backplane to change, thereby converting it into an electrical signal output.

For applications in airflow sensors, when the airflow sensor senses the user's inhalation, the diaphragm of the airflow sensor deforms, converting the air pressure on both sides of the diaphragm of the airflow sensor into changes in the internal capacitor of the sensor to output a signal, thus the airflow sensor can be used as a switch to control the atomizer of electronic cigarettes.

### SUMMARY

The present invention aims to solve at least one of the technical problems existing in the prior art and provide an airflow sensor and an airflow sensor packaging structure.

The purpose of the present invention is achieved by the following technical solutions:

According to a first aspect of the present invention, an airflow sensor is provided. The airflow sensor comprises:

a substrate, a vibrating electrode, and a fixed electrode in a laminated arrangement, wherein the substrate has a back cavity passing through the substrate in the thickness direction thereof;

the vibrating electrode has a vibration-sensitive area, and a gap layer is provided between the vibration-sensitive area and the fixed electrode. The vibrating electrode and the fixed electrode form a variable capacitor. At least one air release hole is provided on the fixed electrode, and the air release hole is connected to the gap layer;

the airflow sensor further comprises at least one pressure equalizing structure, wherein the pressure equalizing structure comprise a pressure equalizing hole and a pressure equalizing channel. The pressure equalizing holes are disposed at a perimeter edge of a vibration-sensitive region of the vibrating electrode, and the pressure equalizing channel is connected to the pressure equalizing hole to establish a continuous flow path in a space outside the back cavity and the airflow sensor;

Wherein the pressure equalizing structure is physically isolated from the gap layer.

According to a second aspect of the present invention, an airflow sensor packaging structure is provided. The airflow sensor packaging structure comprises a baseplate, a housing and the above mentioned airflow sensors;

wherein the baseplate is fixedly connected to the housing to form a cavity, the airflow sensor is fixedly connected to a side surface of the baseplate facing the housing and is located in the cavity;

wherein a first through hole is provided on the baseplate, a second through hole is provided on the housing, the airflow sensor covers the first through hole, and the air flow sensor separates the cavity into at least a back cavity and a front cavity, the back cavity is connected to the first through hole, the front cavity is connected to the external environment via the second through hole, and the back cavity is connected to the front cavity via the pressure equalizing channel.

The airflow sensor and the airflow sensor packaging structure provided by the present invention are intended to provide at least one pressure equalizing structure on the airflow sensor, and the pressure equalizing structure physically isolating itself from the gap layer, so as to establish a continuous flow path in the space between the back cavity of the airflow sensor and the space outside the airflow sensor. It can not only realize that, in the non-working state, the pressure of the side surface of the vibrating electrode facing the back cavity and the side surface of the vibrating electrode away from the back cavity are equalized to prevent the ASIC connected to the airflow sensor from detecting the signal, thereby causing other components to false trigger, but also may prevent the contaminants entering from the pressure equalizing holes from diffusing into the gap layer between the vibrating electrode and the fixed electrode, thereby the failure rate of the product is reduced.

### BRIEF DESCRIPTION OF THE DRAWINGS

To describe technical solutions in embodiments of this application more clearly, the following briefly introduces the accompanying drawings for describing the embodiments. It is clear that the accompanying drawings in the following descriptions show merely some embodiments of this application, and a person skilled in the art may still derive other drawings from these accompanying drawings without creative efforts.

FIG. 1A is a cross-sectional view from the front direction of the airflow sensor, according to an embodiment of the present invention;

FIG. 1B is a top view of the airflow sensor, according to the embodiment in FIG. 1A;

FIG. 2A is a cross-sectional view from the front direction of the airflow sensor, according to another embodiment of the present invention;

FIG. 2B is a top view of the airflow sensor, according to the embodiment in FIG. 2A;

FIG. 3A is a cross-sectional view from the front direction of the airflow sensor, according to another embodiment of the present invention;

FIG. 3B is a top view of the airflow sensor, according to the embodiment in FIG. 3A;

FIG. 4 is a cross-sectional view from the front direction of the airflow sensor, according to another embodiment of the present invention;

FIG. 5 is a cross-sectional view from the front direction of the airflow sensor, according to another embodiment of the present invention;

FIG. 6 is a cross-sectional view from the front direction of the airflow sensor, according to another embodiment of the present invention;

FIG. 7 is a cross-sectional view from the front direction of the airflow sensor packaging structure, according to an embodiment of the present invention.

### DETAILED DESCRIPTION

The above description is only an overview of the technical solution of the present invention, in order to be able to more clearly understand the technical means of the present invention, and can be implemented in accordance with the contents of the specification, and in order to make the above and other purposes, features and advantages of the present invention can be more obvious and easy to understand, the following specially cites some embodiments and with the accompanying drawings, the following is described in detail.

In the description of the present invention, it should be noted that unless otherwise specified and limited, terms such as “set,” “connect,” and “attach” should be broadly interpreted. For example, it can be a fixed connection or a detachable connection, or even an integral connection. It can be a mechanical connection, an electrical connection, or a communicative connection. It can be directly connected or indirectly connected through an intermediate medium. It can refer to either internal communication between two components or the interaction between the two components. Ordinary technicians in this field can understand the specific meanings of the above-mentioned terms in the present invention based on specific circumstances.

At least one embodiment of this application provide an airflow sensor. The airflow senor comprises: a substrate, a vibrating electrode, and a fixed electrode in a laminated arrangement, wherein the substrate has a back cavity passing through the substrate in the thickness direction thereof;

wherein the vibrating electrode has a vibration-sensitive area, and a gap layer is provided between the vibration-sensitive area and the fixed electrode. The vibrating electrode and the fixed electrode form a variable capacitor. At least one air release hole is provided on the fixed electrode, and the air release hole is connected to the gap layer;

the airflow sensor further comprises at least one pressure equalizing structure, wherein the pressure equalizing structure comprise a pressure equalizing hole and a pressure equalizing channel. The pressure equalizing holes are disposed at a perimeter edge of a vibration-sensitive region of the vibrating electrode, and the pressure equalizing channel is connected to the pressure equalizing hole to establish a continuous flow path in a space outside the back cavity and the airflow sensor;

wherein the pressure equalizing structure is physically isolated from the gap layer.

As can be seen from the above, the embodiment of the present application is provided with at least one pressure equalizing structure on the airflow sensor to establish a continuous flow path in the space between the back cavity and the space outside the airflow sensor, and the pressure equalizing holes of the pressure equalizing structure are provided in the vibration non-sensitive area of the vibrating electrode, so as to realize the equalization of pressure between the surface of the side of the vibrating electrode toward the back cavity and the surface of the side of the vibrating electrode away from the back cavity under a non-operating state, so as to prevent the signal from being detected by the ASIC connected with the airflow sensor from causing a false triggering of the other components. Moreover, the pressure equalizing structure is physically isolated from the gap layer, so that the contaminants (e.g., cigarette oil, etc.) entering from the pressure equalizing hole will not diffuse (invade) into the gap layer, thereby perfectly solving the problem of film suction problems caused by contaminants (e.g., cigarette oil, etc.) between the vibrating electrode and the fixed electrode, as well as the resulting problems of false triggering and short circuit.

### Embodiment One

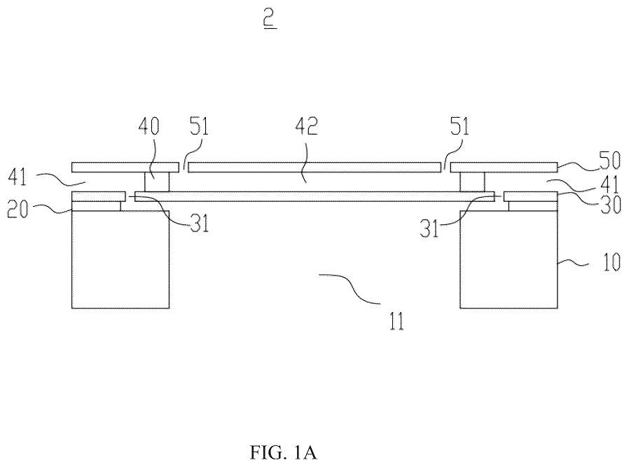

FIG. 1A is a cross-sectional view from the front direction of the airflow sensor, according to an embodiment of the present invention, FIG. 1B is a top view of the airflow sensor, according to the embodiment in FIG. 1A.

As shown in FIG. 1A and FIG. 1B, the airflow sensor 2 comprises a substrate 10, a vibrating electrode 30, and a fixed electrode 50 provided in a laminated arrangement, wherein the substrate 10 has a back cavity 11 passing through in its thickness direction;

the vibrating electrode 30 has a vibration-sensitive area, and a gap layer 42 is provided between the vibration-sensitive area and the fixed electrode 50. The vibrating electrode 30 and the fixed electrode 50 form a variable capacitor. At least one air release hole 51 is provided on the fixed electrode 50, and the air release hole 51 is connected to the gap layer 42;

the airflow sensor 2 further comprises at least one pressure equalizing structure, wherein the pressure equalizing structure comprise a pressure equalizing hole 31 and a pressure equalizing channel 41. The pressure equalizing holes 31 are disposed at a perimeter edge of a vibration-sensitive region of the vibrating electrode 30, and the pressure equalizing channel 41 is connected to the pressure equalizing hole 31 to establish a continuous flow path in a space outside the back cavity 11 and the airflow sensor 2;

wherein the pressure equalizing structure is physically isolated from the gap layer 42.

In the embodiment of the present invention, it is intended to provide at least one pressure equalizing structure on the airflow sensor 2, and the pressure equalizing structure physically isolating itself from the gap layer 42, so as to establish a continuous flow path in the space between the back cavity 11 of the airflow sensor 2 and the space outside the airflow sensor 2. It can not only realize that, in the non-working state, the pressure of the side surface of the vibrating electrode 30 facing the back cavity 11 and the side surface of the vibrating electrode 30 away from the back cavity 11 are equalized to prevent the airflow sensor 2 from being false triggered, but also can prevent the contaminants (e.g., cigarette oil, etc.) entering from the pressure equalizing hole 31 from diffusing (invading) into the gap layer 42, thereby the failure rate of the product is reduced.

Further, a first support body 20 is formed between the vibrating electrode 30 and the substrate 10 to connect a portion of the the vibrating electrode 30 with a portion of the substrate 10, and a second support body 40 is formed between the fixed electrode 50 and the vibrating electrode 30 to connect a portion of the fixed electrode 50 with a portion of the vibrating electrode 30. For example, in some embodiments, both the first support body 20 and the second support body 40 are insulating support bodies, which may be, for example, silicon oxide or silicon nitride or the like. The thickness of the first support body 20 and the second support body 40 is between 2 and 3 um, for example, around 2.5 um. Under this condition, the vibrating electrode 30 and the fixed electrode 50 are opposed to each other and arranged at an insulating distance, so that an oscillation cavity for the vibrating electrode 30 to vibrate is formed between the fixed electrode 50 and the vibrating electrode 30, that is, a gap layer 42 as shown in FIG. 1A is formed.

For example, in this embodiment, the first support body 20 is located at the edge of the substrate 10 to support the vibrating electrode 30, so that the vibrating electrode 30 is suspended above the back cavity 11. Specifically, the vibrating electrode 30 comprises a vibration-sensitive area and a support area, wherein the support area elevates the vibrating electrode 30 above the back cavity 11 through the first support body 20. The second support body 40 is located at the edge of the vibrating electrode 30, so that the fixed electrode 50 is suspended above the vibrating electrode 30 and is insulated from the vibrating electrode 30. It should be noted that the vibrating electrode 30 in this embodiment is a planar membrane structure located directly above the back cavity 11. Generally, when subjected to external force, the vibrating electrode 30 deforms in an outward direction along the geometric center of the vibrating electrode 30, the deformation amount of the vibrating electrode 30 (the amplitude of the deformation of the vibrating electrode 30) decreases sequentially. It should be noted that the vibrating electrode 30 in this embodiment is a planar membrane structure located directly above the back cavity 11. Generally, when subjected to external force, the vibrating electrode 30 deforms in an outward direction along the geometric center of the vibrating electrode 30, the deformation amount of the vibrating electrode 30 (the amplitude of the deformation of the vibrating electrode 30) decreases sequentially.

In some embodiments, the fixed electrode 50 is a single-layer structure, and the entire fixed electrode 50 serves as a conductive electrode to form a variable capacitor with the vibrating electrode 30. In some other embodiments, the fixed electrode 50 may also be a multi-layer structure. The fixed electrode 50 comprises a conductive layer 601, wherein the conductive layer 601 of the fixed electrode 50 forms a variable capacitor with the vibrating electrode 30. The embodiments of the present invention are not limited here.

In this embodiment, the pressure equalizing structure comprises a pressure equalizing hole 31 and a pressure equalizing channel 41. For example, the pressure equalizing holes 31 are disposed at a perimeter edge of a vibration-sensitive region of the vibrating electrode 30, the pressure equalizing channel 41 passes through in a gap between the fixed electrode 50 and the vibrating electrode 30, and is connected to the pressure equalizing hole 31 to establish a continuous flow path in a space outside the back cavity 11 and the airflow sensor 2, so as to realize the equalization of pressure between the surface of the side of the vibrating electrode 30 toward the back cavity 11 and the surface of the side of the vibrating electrode 30 away from the back cavity 11 under a non-operating state, so as to prevent the signal from being detected by the ASIC connected with the airflow sensor 2 from causing a false triggering of the other components.

In some embodiments, the entire pressure equalizing structure is L-shaped. When the airflow of the electronic cigarette enters from the back cavity 11 of the airflow sensor 2, the airflow of the electronic cigarette acts on the vibrating electrode 30, causing the vibrating electrode 30 to deform, and the airflow of the electronic cigarette can be discharged to the space outside the airflow sensor 2 via the pressure equalizing hole 31 on the vibrating electrode 30.Moreover, in this embodiment, the second support body 40 adjacent to the pressure equalizing channel 41 can form a side wall that is configured to block contaminants (e.g., cigarette oil, etc.) entering from the pressure equalizing holes 31 from diffusing (invading) into the gap layer 42 via the pressure equalizing channel 41, thereby it completely solves the problem of film suction of the vibrating electrode 30 and the fixed electrode 50 due to contaminants (e.g., cigarette oil, etc.).

It should be noted that in the manufacturing process of an airflow sensor 2, there are usually thousands of release holes on the fixed electrode 50, and these thousands of release holes are evenly distributed on the fixed electrode 50 for use, therefore the sacrificial layer located between the fixed electrode 50 and the vibrating electrode 30 is removed by solution releasing method. In some embodiments, after the sacrificial layer located between the fixed electrode 50 and the vibration electrode is released to form a gap layer 42, the above-mentioned release holes need to be closed. Then, at least one air release hole 51 is etched on the insulating layer 501 on the edge of the fixed electrode 50 close to the second support body 40, wherein the air release hole 51 passes through the insulating layer 501 in the thickness direction, so that the gap layer 42 is connected to the space outside the airflow sensor 2, thus the air pressure balance is achieved.

Further, the air release hole 51 on the fixed electrode 50 is distributed at the edge close to the second support body 40 to reduce the probability that the airflow containing pollutants (e.g., cigarette oil, etc.) discharged to the space outside the airflow sensor 2 2 through the air release channel re-diffracted into the gap through the air release holes 51, thereby the service life of the product is increase.

Further, the number of air release holes 51 is less than or equal to 100, for example, 50, 60, 70, 80 or 90.

Compared to the existing art that thousands of air release holes 51 are provided on the fixed electrode 50, and all the air release holes 51 are evenly distributed on the fixed electrode 50, adopting the technical solution provided by the embodiments of the present application is capable of significantly increasing the effective overlapping area of the fixed electrode 50 and the vibration electrode, thereby increasing the size of the variable capacitor of the airflow sensor 2 without changing the size of the volume of the airflow sensor 2 itself and thereby enhancing the sensitivity of the detection of the airflow sensor 2.

Specifically, in this embodiment, the air outlet of the pressure equalizing channel 41 is located at the gap between the fixed electrode 50 and the vibrating electrode 30. Therefore, the flow direction of the gas containing contaminants (e.g., cigarette oil, etc.) discharged from the outlet of the pressure equalizing channel 41 is completely different from the opening direction of the air release holes 51, furthermore, the probability of the gas containing contaminants (e.g., cigarette oil, etc.) being bypassed from the air release holes 51 on the fixed electrodes 50 to enter into the gap layer 42 is reduced, and the service life of the product is improved.

### Embodiment Two

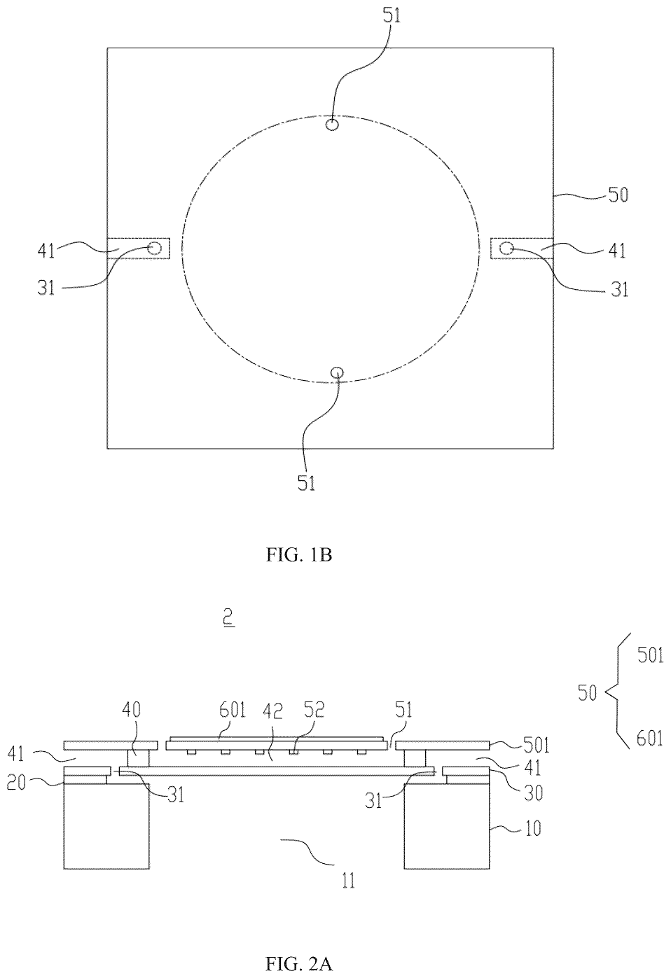

FIG. 2A is a cross-sectional view from the front direction of the airflow sensor, according to another embodiment of the present invention, FIG. 2B is a top view of the airflow sensor, according to the embodiment in FIG. 2A.

As shown in FIG. 2A and FIG. 2B, for example, the difference between FIG. 2A and FIG. 1A is that: in this embodiment, the fixed electrode 50 comprises an insulating layer 501 and a conductive layer 601 fixedly connected to the insulating layer 501, the conductive layer 601 is located on the side of the insulating layer 501 away from the vibrating electrode 30 in the thickness direction of the substrate 10, and the projection of the conductive layer 601 is located within the projection range of the vibration-sensitive area; the air release holes 51 are distributed at the edge close to the second support body 40, and wherein the air release holes 51 only pass through the insulating layer 501 in the thickness direction. Because the air release hole 51 provided on the fixed electrode 50 does not occupy the area where the conductive layer 601 is located, it does not affect the effective overlapping area of the conductive layer 601 and the vibrating electrode 30.

In this embodiment, the pressure equalizing structure comprises a pressure equalizing hole 31 and a pressure equalizing channel 41. For example, the pressure equalizing holes 31 are disposed at a perimeter edge of a vibration-sensitive region of the vibrating electrode 30, the pressure equalizing channel 41 passes through in a gap between the insulating layer 501 of the fixed electrode 50 and the vibrating electrode 30, and the pressure equalizing channel 41 is connected to the pressure equalizing hole 31 to establish a continuous flow path in a space outside the back cavity 11 and the airflow sensor 2.

Similar to embodiment one, in this embodiment, the number of air release holes 51 is less than or equal to 100, and the air release holes 51 are distributed at the perimeter edges of the conductive layer 601 to reduce the probability that airflow containing contaminants (e.g., cigarette oil, etc.) from the space outside the airflow sensor 2 will be injected into the gap layer 42 via the air release holes 51 in a perimeter manner, thereby the product's service life is increased.

For example, in this embodiment, the airflow sensor 2 further comprises a first soldering pad 701 and a second soldering pad 702. The first soldering pad 701 is electrically connected to the conductive layer 601 of the fixed electrode 50 and is used to transmit electrical signals of the conductive layer 601. The second pad is electrically connected to the vibrating electrode 30 and used to transmit the electrical signal of the vibrating electrode 30.

Further, in order to prevent the problem of adhesion caused by the film suction between the fixed electrode 50 and the vibrating electrode 30, an anti-adhesion structure 52 is provided on the side surface of the fixed electrode 50 facing the vibrating electrode 30, so that the adhesion caused by the film suction between the fixed electrode 50 and the vibrating electrode 30 is prevented.

Optionally, the anti-adhesion structure 52 is integrally formed together with the insulating layer 501 501 on the fixed electrode 50.

### Embodiment Three

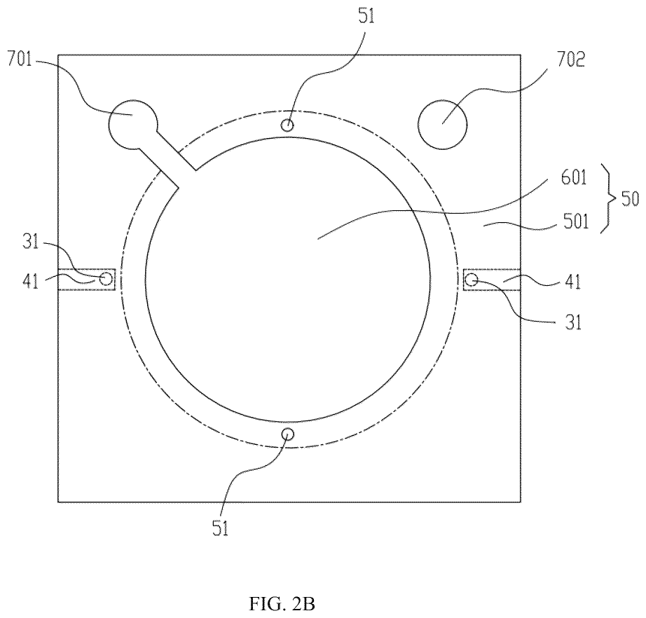

FIG. 3A is a cross-sectional view from the front direction of the airflow sensor, according to another embodiment of the present invention, FIG. 3B is a top view of the airflow sensor, according to the embodiment in FIG. 3A.

As shown in FIG. 3A and FIG. 3B, for example, what is different from the first and second embodiments is that: in this embodiment, the pressure equalizing channel 41 comprises a through hole provided on the fixed electrode 50, and the through hole is connected to the pressure equalizing holes 31 on the vibrating electrode 30 to form a pressure equalizing structure together.

For example, the second support body 40 may be etched in the thickness direction to form a through hole 53, and the orthographic projection of the through hole 53 on the substrate 10 overlaps the orthographic projection of the pressure equalizing hole 31 on the substrate 10, so that the pressure equalizing structure may form a “line-shaped” connecting structure in the thickness direction of the substrate 10. When the airflow of the electronic cigarette enters from the back cavity 11, the pressure equalizing structure establishes a continuous flow path in the space outside the back cavity 11 and the airflow sensor 2, so that in the non-working state, the pressure of the side surface of the vibrating electrode 30 facing the back cavity 11 and the side surface of the vibrating electrode 30 away from the back cavity 11 are equalized to prevent the airflow sensor 2 from being false triggered.

In some embodiments, the sidewalls of the pressure equalizing channel 41 (through hole 53) adjacent to the gap layer 42 are covered with an isolating structure. For example, the isolating structure and the insulating layer 501 on the fixed electrode 50 are integrally formed. That is, the sidewalls of the through hole 53 may be covered by an insulating layer 501 of the fixed electrode 50, thereby forming a pressure equalizing channel 41 comprising an insulating layer 501, which is jointly configured to block the diffusion (invasion) of an airflow containing contaminants (e.g., cigarette oil, etc.) into the gap layer 42 between the vibrating electrode 30 and the fixed electrode 50.

Unlike embodiment one and embodiment two, in this embodiment, the air outlet of the pressure equalizing channel 41 is located on the fixed electrode 50.

In this embodiment, the pressure equalizing holes 31 and the air release holes 51 are arranged at a certain angle, for example, the pressure equalizing holes 31 are arranged in the horizontal direction, the air release holes 51 are arranged in the vertical direction, or, the pressure equalizing holes 31 are arranged in the perimeter direction close to the vibration-sensitive area, and the air release holes 51 are arranged at the edge close to the center of the vibration-sensitive area, in order to reduce the probability that the airflow containing pollutants (e.g., cigarette oil, etc.) discharged to the external space of the airflow sensor 2 via the pressure equalizing holes 31 will enter into the gap layer 42, thus the service life of the product is increased. It should be understood that in the embodiments of the present application, as long as the pressure equalizing holes 31 and the air release holes 51 are arranged as far apart as possible, the relative positional relationship between the pressure equalizing holes 31 and the air release holes 51 is not strictly limited.

### Embodiment Four

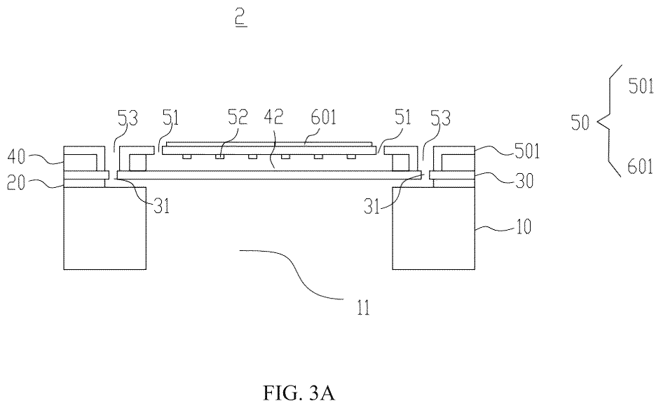

FIG. 4 is a cross-sectional view from the front direction of the airflow sensor, according to another embodiment of the present invention;

As shown in FIG. 4, for example, in this embodiment, the pressure equalizing structure comprises both the pressure equalizing hole 31 and the pressure equalizing channel 41 in embodiment two and the pressure equalizing hole 31 and the through hole 53 in embodiment three, i.e., this embodiment is a combination of embodiment two and embodiment three, both of which can not only equalize the pressure between the side surface of the vibrating electrode 30 facing the back cavity 11 and the side surface of the vibrating electrode 30 away from the back cavity 11 under a non-working state to prevent the airflow sensor 2 from being false triggered, but also be able to prevent the airflow containing pollutants (e.g., cigarette oil, etc.) from spreading toward the gap layer 42 via the pressure equalizing hole 31, to reduce the lapse rate of the airflow sensor 2 when it is operating thereby.

### Embodiment Five

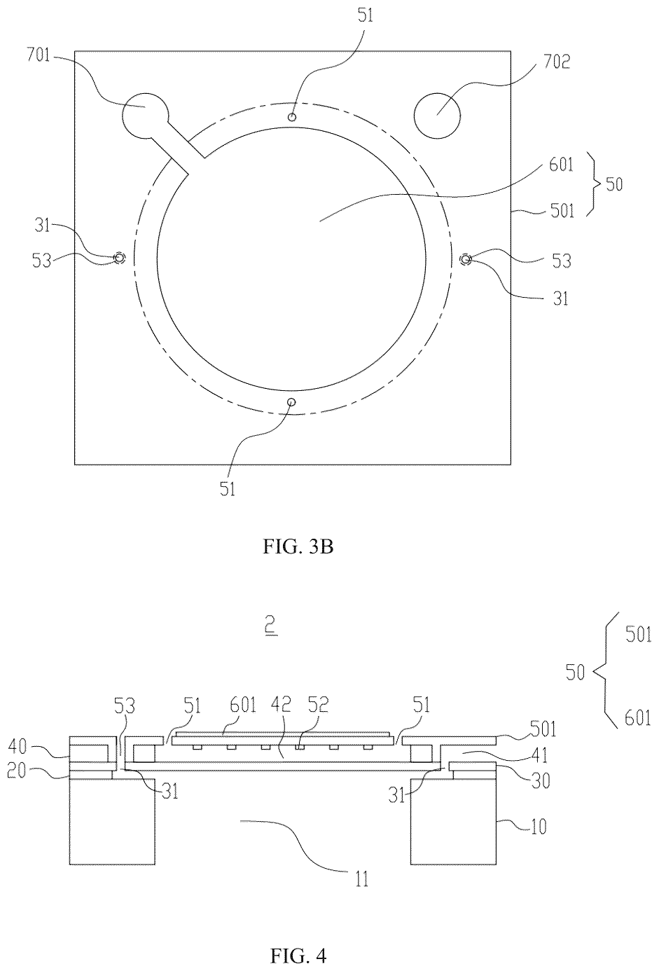

FIG. 5 is a cross-sectional view from the front direction of the airflow sensor, according to another embodiment of the present invention;

As shown in FIG. 5, for example, this embodiment is an optimized arrangement setup based on embodiment three, by optimally arranging the air release holes 51 of the fixed electrode 50, the pressure equalizing holes 31 of the vibrating electrode 30, and the pressure equalizing channels 41 passing through the gap between the fixed electrode 50 and the vibrating electrode 30, e.g., the air release holes 51 of the fixed electrode 50 are arranged in the horizontal direction and the pressure equalizing holes 31 of the vibrating electrode 30 are arranged in the vertical direction; or the air release holes 51 of the fixed electrode 50 are arranged in a vertical direction and the pressure equalizing holes 31 of the vibrating electrode 30 are arranged in a horizontal direction; or the air release holes 51 of the fixed electrode 50 are arranged close to the center of the vibration-sensitive area and the pressure equalizing holes 31 of the vibrating electrode 30 are arranged at the perimeter edge close to the vibration-sensitive area, so as to increase the distance between the air release holes 51 of the fixed electrode 50 and the pressure equalizing holes 31 of the vibration electrode, in order to reduce the probability that the airflow containing pollutants (e.g., cigarette oil, etc.) discharged to the space outside the airflow sensor 2 via the pressure equalizing holes 31 will enter into the gap layer 42, thus the service life of the product is increased.

### Embodiment Six

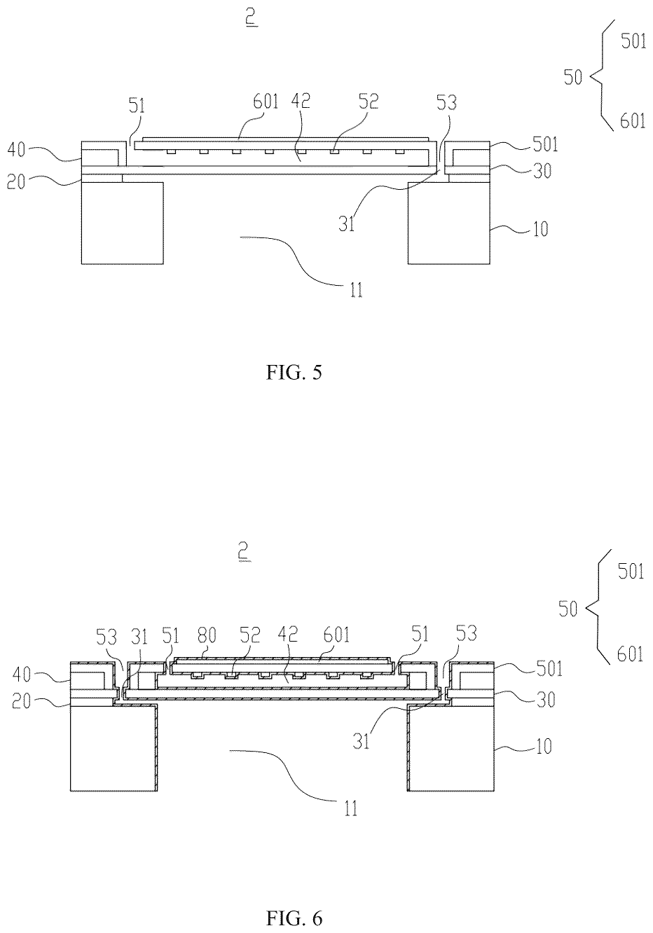

FIG. 6 is a cross-sectional view from the front direction of the airflow sensor, according to another embodiment of the present invention;

As shown in FIG. 6, for example, in some embodiments, what is different from the previous embodiment is that: the airflow sensor 2 comprises an oleophobic layer 80, wherein the oleophobic layer 80 is disposed on the surfaces of the vibrating electrode 30 and the fixed electrode 50 and covers the side walls of the pressure equalizing hole 31, the gap layer 42 channel and the air release hole 51.

The oleophobic layer 80, for example, is a SAM material, so that there is a thin oleophobic layer 80 on all layers, and when contaminants (e.g., cigarette oil, etc.) enter into the interstitial layer, they will accumulate on the surface of the vibrating electrode 30 without causing the vibrating electrode 30 and the fixed electrode 50 to absorb, meanwhile, the airflow sensor 2 in the electronic cigarette will not fail during operation. Further, an oleophobic layer 80 may also be added to other structures. For example, a sidewall of the back cavity 11 of the substrate 10 is also coated with an oleophobic layer 80, to further minimize the occurrence of suction of the fixed electrodes 50 and the vibrating electrodes 30, thereby the failure rate of the product is reduced.

### Embodiment Seven

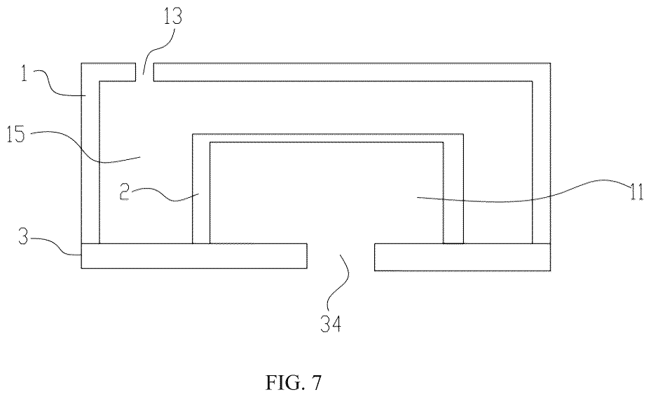

FIG. 7 is a cross-sectional view from the front direction of the airflow sensor packaging structure, according to an embodiment of the present invention.

As shown in FIG. 7, according to another aspect of the present invention, an airflow sensor 2 packaging structure is provided. The airflow sensor 2 packaging structure comprises a baseplate 3, a housing 1 and the above mentioned airflow sensor 2; wherein the baseplate 3 is fixedly connected to the housing 1 to form a cavity, the airflow sensor 2 is fixedly connected to a side surface of the baseplate 3 facing the housing 1 and is located in the cavity; wherein a first through hole 34 is provided on the baseplate 3, a second through hole 13 is provided on the housing 1, the airflow sensor 2 covers the first through hole 34, and the air flow sensor separates the cavity into at least a back cavity 11 and a front cavity 15, the back cavity 11 is connected to the first through hole 34, to allow the airflow of electronic cigarette to enter from the back cavity 11 of the airflow sensor 2, the front cavity 15 is connected to the external environment via the second through hole 13, and the back cavity 11 is connected to the front cavity 15 via the pressure equalizing channel 41, in order to sense the pressure difference between the external environment of the airflow sensor 2 packaging structure and a corresponding first through hole 34 of the airflow sensor 2 packaging structure.

Thus, the airflow sensor 2 and the airflow sensor 2 packaging structure provided by the present invention are intended to provide at least one pressure equalizing structure on the airflow sensor 2, and the pressure equalizing structure physically isolating itself from the gap layer 42, so as to establish a continuous flow path in the space between the back cavity 11 of the airflow sensor 2 and the space outside the airflow sensor 2. It can not only realize that, in the non-working state, the pressure of the side surface of the vibrating electrode 30 facing the back cavity 11 and the side surface of the vibrating electrode 30 away from the back cavity 11 are equalized to prevent the ASIC connected to the airflow sensor 2 from detecting the signal, thereby causing other components to false trigger, but also may prevent the contaminants entering from the pressure equalizing holes 31 from diffusing into the gap layer 42 between the vibrating electrode 30 and the fixed electrode 50, thereby the failure rate of the product is reduced.

Further, a first support body 20 is formed between the vibrating electrode 30 and the substrate 10 to connect a portion of the the vibrating electrode 30 with a portion of the substrate 10, and a second support body 40 is formed between the fixed electrode 50 and the vibrating electrode 30 to connect a portion of the fixed electrode 50 with a portion of the vibrating electrode 30;

in a direction perpendicular to the thickness of the substrate 10, the air release hole 51 is distributed at the edge close to the second support body 40.

Further, the number of the air release holes 51 is less than or equal to 100.

Further, the fixed electrode 50 comprises an insulating layer 501 and a conductive layer 601 fixedly connected to the insulating layer 501. In the thickness direction of the substrate 10, the conductive layer 601 is disposed on a side of the insulating layer 501 away from the vibrating electrode 30, and the projection of the conductive layer 601 is located within a projection of the vibration-sensitive region;

and wherein the air release holes 51 only pass through the insulating layer 501 in the thickness direction.

In some embodiments, the pressure equalizing channel 41 is disposed through the gap between the fixed electrode 50 and the vibrating electrode 30.

Further, the air outlet of the pressure equalizing channel 41 is located at the gap between the fixed electrode 50 and the vibrating electrode 30.

In some embodiments, the pressure equalization channel comprises a through hole provided in the fixed electrode 50, wherein the through hole is connected to the pressure equalization hole.

Further, the air outlet of the pressure equalizing channel 41 is located on the fixed electrode 50.

Further, the side wall of the pressure equalizing channel 41 adjacent to the gap layer 42 is covered with an isolating structure.

Further, the isolating structure is integrally formed together with the insulating layer 501 on the fixed electrode 50.

Further, an anti-adhesion structure 52 is provided on a side surface of the fixed electrode 50 facing the vibrating electrode 30.

Further, the anti-adhesion structure 52 is integrally formed together with the insulating layer 501 on the fixed electrode 50.

Further, the airflow sensor 2 comprises an oleophobic layer 80,

wherein the oleophobic layer 80 is disposed on the surfaces of the vibrating electrode 30 and the fixed electrode 50 and covers the side walls of the pressure equalizing hole 31, the gap layer 42 channel and the air release hole 51.

Finally, it should be noted that: the above describes the embodiments of this application. However, these embodiments are only for illustrative purposes and not to limit the scope of the present application. The scope of this application is limited by the attached claims and their equivalents. Without departing from the scope of this application, technicians in the art may make various substitutions and modifications, all of which should fall within the scope of this application.

1. An airflow sensor, wherein the airflow sensor comprises:
a substrate, a vibrating electrode, and a fixed electrode in a laminated arrangement, wherein the substrate has a back cavity passing through the substrate in the thickness direction thereof;
the vibrating electrode has a vibration-sensitive area, and a gap layer is provided between the vibration-sensitive area and the fixed electrode, the vibrating electrode and the fixed electrode form a variable capacitor, an air release hole is provided on the fixed electrode, and the air release hole is connected to the gap layer;
the airflow sensor further comprises at least one pressure equalizing structure, wherein the pressure equalizing structure comprise a pressure equalizing hole and a pressure equalizing channel, the pressure equalizing hole is disposed at a perimeter edge of a vibration-sensitive region of the vibrating electrode, and the pressure equalizing channel is connected to the pressure equalizing hole to establish a continuous flow path in a space outside the back cavity and the airflow sensor;
wherein the pressure equalizing structure is physically isolated from the gap layer, the projection of the pressure equalizing structure does not overlap with the projection of the back cavity in the thickness direction of the substrate.

2. The airflow sensor according to claim 1, wherein a first support body is formed between the vibrating electrode and the substrate to connect a portion of the vibrating electrode with a portion of the substrate, and a second support body is formed between the fixed electrode and the vibrating electrode to connect a portion of the fixed electrode with a portion of the vibrating electrode;
in a direction perpendicular to the thickness of the substrate, the air release hole is distributed at the edge close to the second support body.

3. The airflow sensor according to claim 2, wherein the number of the air release holes is less than or equal to 100.

4. The airflow sensor according to claim 2, wherein the fixed electrode comprises an insulating layer and a conductive layer fixedly connected to the insulating layer, in the thickness direction of the substrate, the conductive layer is disposed on a side of the insulating layer away from the vibrating electrode, and the projection of the conductive layer is located within a projection of the vibration-sensitive region;
and wherein the air release hole only passes through the insulating layer in the thickness direction.

5. The airflow sensor according to claim 2, wherein the pressure equalizing channel is disposed through the gap between the fixed electrode and the vibrating electrode.

6. The airflow sensor according to claim 5, wherein the air outlet of the pressure equalizing channel is located at the gap between the fixed electrode and the vibrating electrode.

7. The airflow sensor according to claim 4, wherein the pressure equalization channel comprises a through hole provided in the fixed electrode, wherein the through hole is connected to the pressure equalization hole.

8. The airflow sensor according to claim 7, wherein the air outlet of the pressure equalizing channel is located on the fixed electrode.

9. The airflow sensor according to claim 7, wherein the side wall of the pressure equalizing channel adjacent to the gap layer is covered with an isolating structure.

10. The airflow sensor according to claim 9, wherein the isolating structure is integrally formed together with the insulating layer on the fixed electrode.

11. The airflow sensor according to claim 7, wherein an anti-adhesion structure is provided on a side surface of the fixed electrode facing the vibrating electrode.

12. The airflow sensor according to claim 11, wherein the anti-adhesion structure is integrally formed together with the insulating layer on the fixed electrode.

13. The airflow sensor according to claim 1, wherein the airflow sensor comprises an oleophobic layer,
wherein the oleophobic layer is disposed on the surfaces of the vibrating electrode and the fixed electrode and covers the side walls of the pressure equalizing hole, the gap layer channel and the air release hole.

14. An airflow sensor packaging structure, wherein the airflow sensor packaging structure comprises a baseplate, a housing and the airflow sensor according to claim 1;
wherein the baseplate is fixedly connected to the housing to form a cavity, the airflow sensor is fixedly connected to a side surface of the baseplate facing the housing and is located in the cavity;
wherein a first through hole is provided on the baseplate, a second through hole is provided on the housing, the airflow sensor covers the first through hole, and the air flow sensor separates the cavity into at least a back cavity and a front cavity, the back cavity is connected to the first through hole, the front cavity is connected to the external environment via the second through hole, and the back cavity is connected to the front cavity via the pressure equalizing channel.
